(19) United States
(12) Patent Application Publication
(10) Pub. No.: US 2026/0283002 A1
(43) Pub. Date: Sep. 17, 2026

(54) SENSOR PACKAGE STRUCTURE AND MANUFACTURING METHOD THEREOF

(71) Applicant: TONG HSING ELECTRONIC INDUSTRIES, LTD., Taoyuan City (TW)

(72) Inventors: YOU-WEI CHANG, Taoyuan City (TW); CHIEN-CHEN LEE, Taoyuan City (TW); LI-CHUN HUNG, Taoyuan City (TW)

(21) Appl. No.: 19/670,005

(22) Filed: May 7, 2026

Related U.S. Application Data
(62) Division of application No. 17/896,090, filed on Aug. 26, 2022.

(30) Foreign Application Priority Data
May 5, 2022 (TW) 111116912

(51) Int. Cl. H10W 74/10; H10W 76/12; H10W 76/60

(52) U.S. Cl. CPC H10W 74/114; H10W 76/12; H10W 76/60

(57) ABSTRACT

A sensor package structure and a manufacturing method thereof. The sensor package structure includes a substrate, a sensor chip and a package cover. The substrate has first and second substrate surfaces that are opposite to each other. The sensor chip is disposed on the first substrate surface and has a sensing area. The package cover includes a molding layer, a supporting layer and a light-transmitting layer. The molding layer surrounds the sensing area and is disposed on the first substrate surface. The supporting layer surrounds the sensing area and is disposed on the molding layer. The light-transmitting layer is disposed on the supporting layer and covers the substrate, the sensor chip, the molding layer and the supporting layer. The light-transmitting layer, the supporting layer, and the molding layer are formed to surround an enclosed space, and the sensing area is located in the enclosed space.

### CROSS-REFERENCE TO RELATED PATENT APPLICATION

This application is a divisional application of the U.S. Patent Application Ser. No. 17/896,090, filed on August 26, 2022, and entitled “SENSOR PACKAGE STRUCTURE AND MANUFACTURING METHOD THEREOF,” now pending, the entire disclosures of which are incorporated herein by reference. Moreover, this divisional application contains claims based on Invention II and Species 2A according to the Restriction Requirement dated December 30, 2024.

This application claims the benefit of priority to Taiwan Patent Application No. 111116912, filed on May 5, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure and a manufacturing method thereof, and more particularly, to a sensor package structure and a manufacturing method thereof.

### BACKGROUND OF THE DISCLOSURE

Sealing epoxy is widely used in a glass mounting process of certain image sensors, such as CMOS image sensor elements. However, since the sealing epoxy is in a fluid state during a manufacturing process of the image sensors, a structure thereof is difficult to be controlled. Although molding covers made of glass have been developed to better control the precision of a sealing structure of the image sensors, glass molding covers typically suffer from glass damage, scratches, or resin intrusion as a consequence of improper contact during molding processes.

### SUMMARY OF THE DISCLOSURE

In response to the above-referenced technical inadequacies, the present disclosure provides a sensor package structure and a manufacturing method thereof which can address glass damage and resin intrusion issues.

In one aspect, the present disclosure provides a sensor package structure, which includes a substrate, a sensor chip and a package cover. The substrate has a first substrate surface and a second substrate surface that are opposite to each other. The sensor chip is disposed on the first substrate surface and having a sensing area, and the sensor chip is electrically connected to the substrate. The package cover includes a molding layer, a supporting layer and a light-transmitting layer. The molding layer surrounds the sensing area and is disposed on the first substrate surface. The supporting layer surrounds the sensing area and is disposed on the molding layer. The light-transmitting layer is disposed on the supporting layer and covers the substrate, the sensor chip, the molding layer and the supporting layer. wherein the light-transmitting layer, the supporting layer, and the molding layer are formed to surround an enclosed space, and the sensing area is located in the enclosed space.

In another aspect, the present disclosure provides a manufacturing method of a sensor package structure, which includes: providing a light-transmitting layer having a top surface and a bottom surface that are opposite to each other, in which the light-transmitting layer has at least one predetermined sensing area on the bottom surface; forming a supporting layer on the bottom surface of the light-transmitting layer, in which the supporting layer surrounds the at least one predetermined sensing area; forming a molding layer on the supporting layer by a molding process, in which the molding layer surrounds the at least one predetermined sensing area; cutting the light-transmitting layer, the supporting layer and the molding layer by using a dicing process to form at least one package cover; providing a substrate having a first substrate surface and a second substrate surface that are opposite to each other; disposing a sensor chip on the first substrate surface and electrically connecting the sensor chip to the substrate, in which the sensor chip has a sensing area; and disposing the at least one package cover on the first substrate surface of the substrate, in which the light-transmitting layer, the supporting layer, the molding layer form to surround an enclosed space, and the sensing area is located in the enclosed space.

Therefore, in the sensor package structure and the manufacturing method thereof provided by the present disclosure, the package cover that is free of sealing epoxy resin is formed, thereby allowing a height and a width of the package cover to be precisely controlled, and effectively preventing the resin intrusion issue. Furthermore, process defects that may occur during the manufacturing process of the sensor package structure can be avoided, such as glass damage, scratches, or resin intrusion to a glass molding cover due to any improper contact during the molding process.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of one implementation of the sensor package structure according to a first embodiment of the present disclosure;

FIG. 2 is a schematic cross-sectional view of another implementation of the sensor package structure according to the first embodiment of the present disclosure;

FIG. 3 is a flowchart of a manufacturing method for a sensor package structure according to a second embodiment of the present disclosure; and

FIGS. 4 to 8 are schematic diagrams illustrating steps of the manufacturing method for the sensor package structure according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

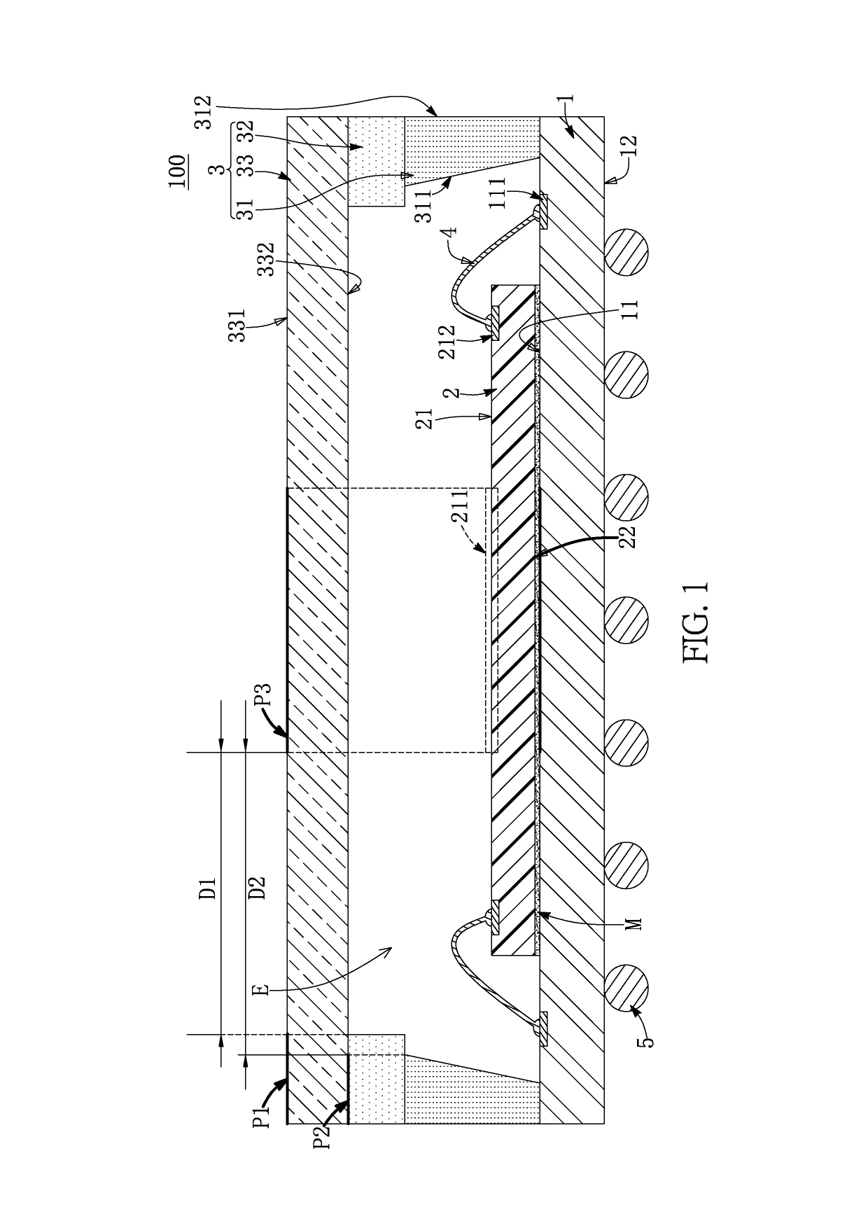

FIG. 1 is a schematic cross-sectional view of one implementation of the sensor package structure according to a first embodiment of the present disclosure. Reference is made to FIG. 1, and a first embodiment of the present disclosure provides a sensor package structure 100. The sensor package structure 100 includes a substrate 1, a sensor chip 2 and a package cover 3 in the present embodiment.

In this embodiment, the substrate 1 is square or rectangular, but the present disclosure is not limited thereto. The substrate 1 has a first substrate surface 11 and a second substrate surface 12 that are opposite to each other. The substrate 1 can be, for example, a printed circuit board, and is formed with a plurality of pads 111 located outside the sensor chip 2. In this embodiment, the plurality of pads 111 are annularly arranged around the sensor chip 2, but the present disclosure is not limited thereto.

In addition, the substrate 1 can also be provided with a plurality of solder balls 5 on the second substrate surface 12, and the sensor package structure 100 can be soldered and fixed to an electronic component (not shown in FIG. 1) through the plurality of solder balls 5. Accordingly, the sensor package structure 100 can be electrically coupled to the electronic component.

The sensor chip 2 is disposed on the first substrate surface 11, and the sensor chip 2 has a sensing area 211 (on an upper surface 21). The sensor chip 2 is illustrated as an image sensor chip in the present embodiment, but it is not limited thereto. Specifically, (a lower surface 22 of) the sensor chip 2 is fixed on the first substrate surface 11 of the substrate 1, and the sensor chip 2 is located inside the plurality of pads 111. In addition, the sensing area 211 is located at a center of the upper surface 21 of the sensor chip 2, but the present disclosure is not limited thereto.

The lower surface 22 of the sensor chip 2 and the first substrate surface 11 are bonded and fixed to each other by an adhesive material M. The adhesive material M can be, for example, a viscous thermally conductive adhesive, but the present disclosure is not limited thereto. For example, in other embodiments that are not shown in the present disclosure, the adhesive material M can also be omitted or replaced with other elements. In the present embodiment, the sensor chip 2 can be electrically connected to the substrate 1. For example, the substrate 1 has a plurality of first pads 111 provided on the first substrate surface 11, and a plurality of second pads 212 are located outside the sensing area 211 and disposed on the upper surface 21 of the sensor chip 2. The plurality of first pads 111 are connected to the plurality of second pads 212 respectively through a plurality of metal wires 4.

The package cover 3 includes a molding layer 31, a supporting layer 32 and a light-transmitting layer 33. The light-transmitting layer 33 serves as a top of the package cover 3, and the molding layer 31 and the supporting layer 32 cooperatively form a sidewall of the package cover 3 to support the light-transmitting layer 33.

Specifically, the molding layer 31 surrounds a periphery of the sensing area 211 and is disposed on the first substrate surface 11. The molding layer 31 can be formed of a molding material, such as a polymer material or a composite material, in which the polymer material can be, for example, polyimide (PI), benzocyclobutene (BCB), epoxy resin or silicone rubber, and the like, and the composite material can be, for example, glass fiber reinforced thermosetting plastics, bulk molding materials and other adhesive insulating materials or dielectric materials. The molding material can also be materials with shading properties, and thus can be used to prevent glare. The molding layer 31 can be formed by a compression molding process or an injection molding process.

The supporting layer 32 surrounds the periphery of the sensing area 211 and is disposed on the molding layer 31. In addition to forming a cover structure together with the molding layer 31 and the light-transmitting layer 33, the supporting layer 32 is also made of a light-absorbing material as an anti-glare layer for preventing glare in the image sensor. The supporting layer 32 can be made of a hard material, for example, a material commonly used for manufacturing a black matrix, such as chromium (Cr), nickel (Ni), graphene, black ink, or black photoresist.

The light-transmitting layer 33 is illustrated as a piece of flat, transparent glass in the present embodiment, but the present disclosure is not limited thereto. The light-transmitting layer 33 is disposed on the supporting layer 32 and covers the substrate 1, the sensor chip 2, the molding layer 31 and the supporting layer 32. The light-transmitting layer 33, the supporting layer 32 and the molding layer 31 are formed to surround an enclosed space E, and the sensing area 211 is located within the enclosed space E. The light-transmitting layer 33 has a top surface 331 and a bottom surface 332 that are opposite to each other, and the supporting layer 32 contacts the bottom surface 332.

In this embodiment, an area of a first vertical projection P1 of the supporting layer 32 projected onto the bottom surface 332 is larger than an area of a second vertical projection P2 of the molding layer 31 projected onto the bottom surface 332. In more detail, the supporting layer 32 substantially completely covers the molding layer 31, not only for the purpose of forming a stable support structure and a good anti-glare structure, but also for avoiding contact with and damage to the light-transmitting layer 33 during a molding process of the molding layer 31.

Furthermore, a third vertical projection P3 of the sensing area 211 projected onto the bottom surface 332 is separated from the first vertical projection P1 and the second vertical projection P2 by a first distance D1 and a second distance D2, respectively, and the second distance D2 is greater than the first distance D1. It should be noted that the supporting layer 32 does not overlap with the sensing area 211, that is, the second distance D2 is not zero. Further, on a premise that a detection range of the sensing area 211 needs to be considered, the second distance D2 is at least greater than a distance from an edge of the sensing area 211 to an edge of the sensor chip 2 on the same side.

In this embodiment, the molding layer 31 has an inner surface 311 adjacent to the enclosed space E and an outer surface 312 away from the enclosed space E, and the inner surface 311 is inclined to the first substrate surface 11. That is, from the cross-sectional view, a part of the sidewall of the package cover 3 formed by the molding layer 31 is trapezoidal.

It should be noted that, in one implementation of the first embodiment of the present disclosure, as shown in FIG. 1, the plurality of first pads 111, the plurality of second pads 212 and the plurality of metal wires 4 are all located in the enclosed space E. That is, in this implementation, the molding layer 31 further directly contacts the first substrate surface 11 of the substrate 1, and the package cover 3 cooperatively formed by the molding layer 31, the supporting layer 32 and the light-transmitting layer 33 directly surround the sensor chip 1, the plurality of first pads 111, the plurality of second pads 212 and the plurality of metal wires 4 in the enclosed space E.

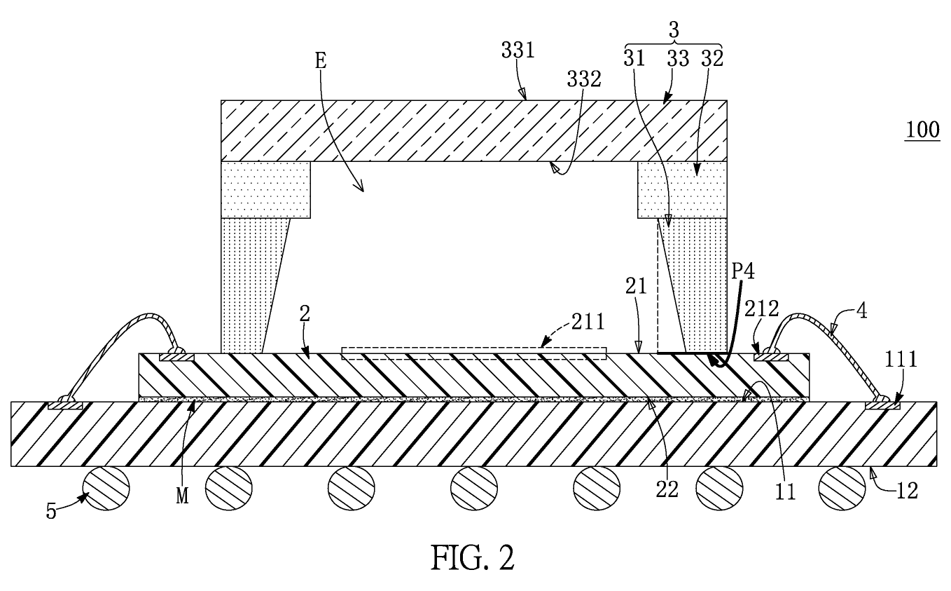

FIG. 2 is a schematic cross-sectional view of another implementation of the sensor package structure according to the first embodiment of the present disclosure. Since the implementation of FIG. 2 is similar to the implementation of FIG. 1, details regarding the same elements will not be repeated herein, and differences between the implementations of FIG. 2 and FIG. 1 are described as follows:

In the embodiment of FIG. 2, the molding layer 31 is disposed on the upper surface 21 of the sensor chip 2, that is, the molding layer 31 does not directly contact the first substrate surface 11 of the substrate 1, but directly contacts the upper surface 21 of the sensor chip 2. Therefore, a fourth vertical projection P4 of the molding layer 31 projected onto the sensor chip 2 is located between the sensing area 211 and the plurality of second pads 212, such that the sensor chip 2, the plurality of first pads 111 and the plurality of metal wires 4 are located outside the enclosed space E.

Therefore, the package cover 3 that is free from sealing epoxy resin is formed, thereby effectively preventing the resin intrusion issue. Furthermore, process defects that may occur during the manufacturing process of the sensor package structure 100 can be avoided, such as glass damage, scratches, or resin intrusion to a glass molding cover due to any improper contact during the molding process.

In addition, the supporting layer 32 in the package cover 3 can not only form a stable support structure and a good anti-glare structure, but also avoid contact with and damage to the light-transmitting layer 33 during the molding process of the molding layer 31.

### Second Embodiment

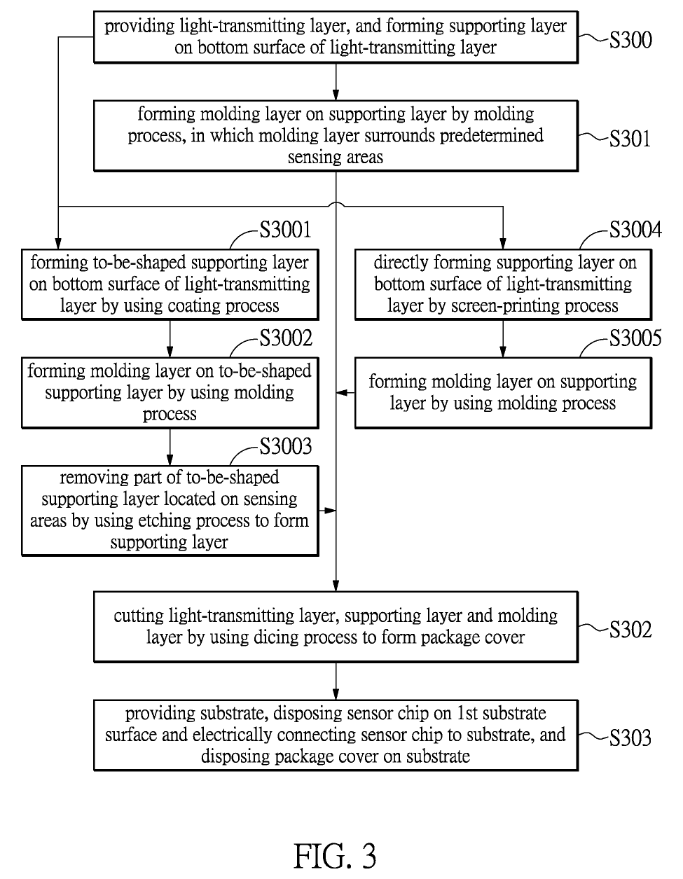

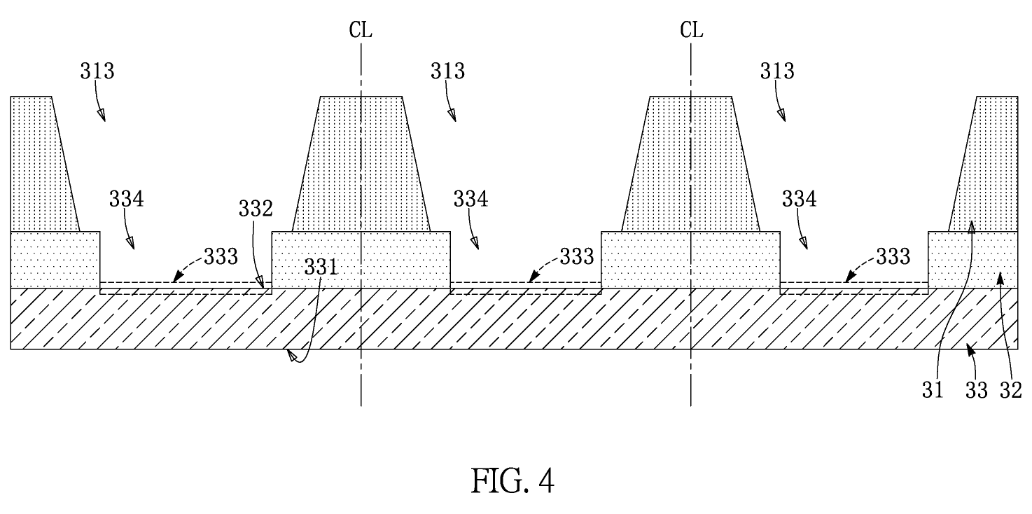

Reference is made to FIGS. 3 to 8, in which FIG. 3 is a flowchart of a manufacturing method for a sensor package structure according to a second embodiment of the present disclosure, and FIGS. 4 to 8 are schematic diagrams illustrating steps of the manufacturing method for the sensor package structure according to the second embodiment of the present disclosure. It should be noted that features of each element in the manufacturing method of the sensor package structure provided by the second embodiment are similar to those described in the previous embodiments, and are not repeated hereinafter. In addition, the second embodiment takes the implementations of FIGS. 1 and 2 as examples. The sensor package structures provided in FIGS. 1 and 2 can also be manufactured by using the manufacturing method of the sensor package structure provided by the second embodiment.

In another aspect, the present disclosure provides a manufacturing method of a sensor package structure, which includes the following steps:

Step S300: providing a light-transmitting layer, and forming a supporting layer on a bottom surface of the light-transmitting layer. For example, the light-transmitting layer 33 can have a top surface 331 and a bottom surface 332 that are opposite to each other, and the light-transmitting layer 33 has at least one predetermined sensing area 333 on the bottom surface 332 (or a plurality of predetermined sensing areas 333, as shown in FIG. 4), and the supporting layer 32 surrounds the plurality of predetermined sensing areas 333 and is formed on the bottom surface 332 of the light-transmitting layer 33. In other words, the supporting layer 32 includes a plurality of recesses 334 corresponding to the plurality of predetermined sensing areas 333 that respectively expose the plurality of predetermined sensing areas 333 on the bottom surface 332 of the light-transmitting layer 33.

Step S301: forming a molding layer on the supporting layer by a molding process, in which the molding layer surrounds the plurality of predetermined sensing areas. As shown in FIG. 4, the molding layer 31 is also formed on the supporting layer 32 to surround the plurality of predetermined sensing areas 333, and the molding layer 31 includes a plurality of valley regions 313 respectively exposing the plurality of predetermined sensing areas 333 on the bottom surface 332 of the light-transmitting layer 33.

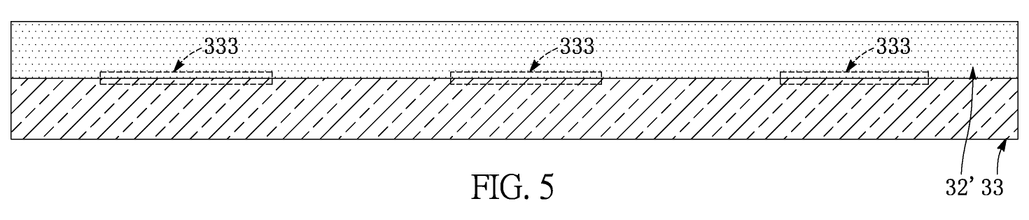

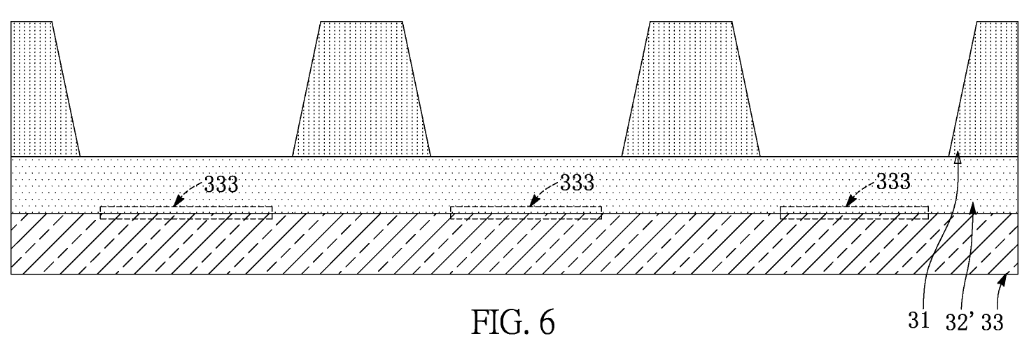

Optionally, FIG. 5, FIG. 6, and FIG. 4 can be referred to in the given order. In some embodiments, steps S300 and S301 can be implemented by the following steps:

Step S3001: forming a to-be-shaped supporting layer on the bottom surface of the light-transmitting layer by using a coating process.

Step S3002: forming the molding layer on the to-be-shaped supporting layer by using the molding process.

S3003: removing a part of the to-be-shaped supporting layer located on the plurality of predetermined sensing areas by using an etching process to form the supporting layer.

As shown in FIGS. 4 and 5, a to-be-shaped supporting layer 32' can be formed on the bottom surface 332 of the light-transmitting layer 33 through a coating process, and then a molding layer 31 is formed on the to-be-shaped supporting layer 32' by the molding process. Then, a part of the to-be-shaped supporting layer 32' on the plurality of predetermined sensing areas 333 are removed through an etching process (e.g., a photolithography process or a laser etching process) to form the supporting layer 32.

In addition, it should be noted that since fluid sealing epoxy resin is not used in the process of forming the supporting layer 32 and the molding layer 33, a structural configuration of the package cover (such as that concerning height and width) can be precisely controlled during the manufacturing process. In addition, since the glass molding cover (i.e., the light-transmitting layer 33) is protected by the supporting layer 32 during the molding process and does not contact the molding layer 33 (or a mold for forming the molding layer 33), the glass molding cover can avoid damage, scratches or resin intrusions.

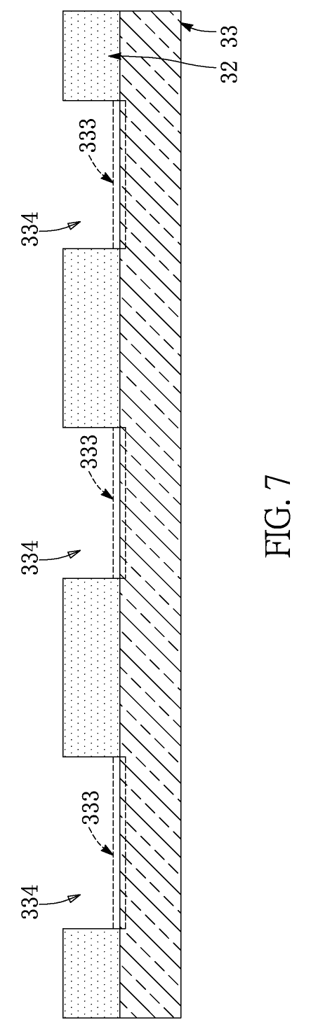

Optionally, FIG. 7 and FIG. 4 can be referred to in the given order. In some embodiments, steps S300 and S301 can be implemented by the following steps:

Step S3004: directly forming the supporting layer on the bottom surface of the light-transmitting layer by a screen-printing process.

Step S3005: forming the molding layer on the supporting layer by using the molding process.

As shown in FIGS. 7 and 4, the supporting layer 32 having the plurality of recesses 334 can be directly formed on the bottom surface 332 of the light-transmitting layer 33 by the screen-printing process, and then the molding layer 31 can be formed on the supporting layer 32 by the molding process.

Therefore, in this way, the structural configuration of the package cover (e.g., that involving height and width) can be precisely controlled during the manufacturing process, and the light-transmitting layer 33 can be protected by the supporting layer 32 during the molding process to avoid damage, scratches or resin intrusions.

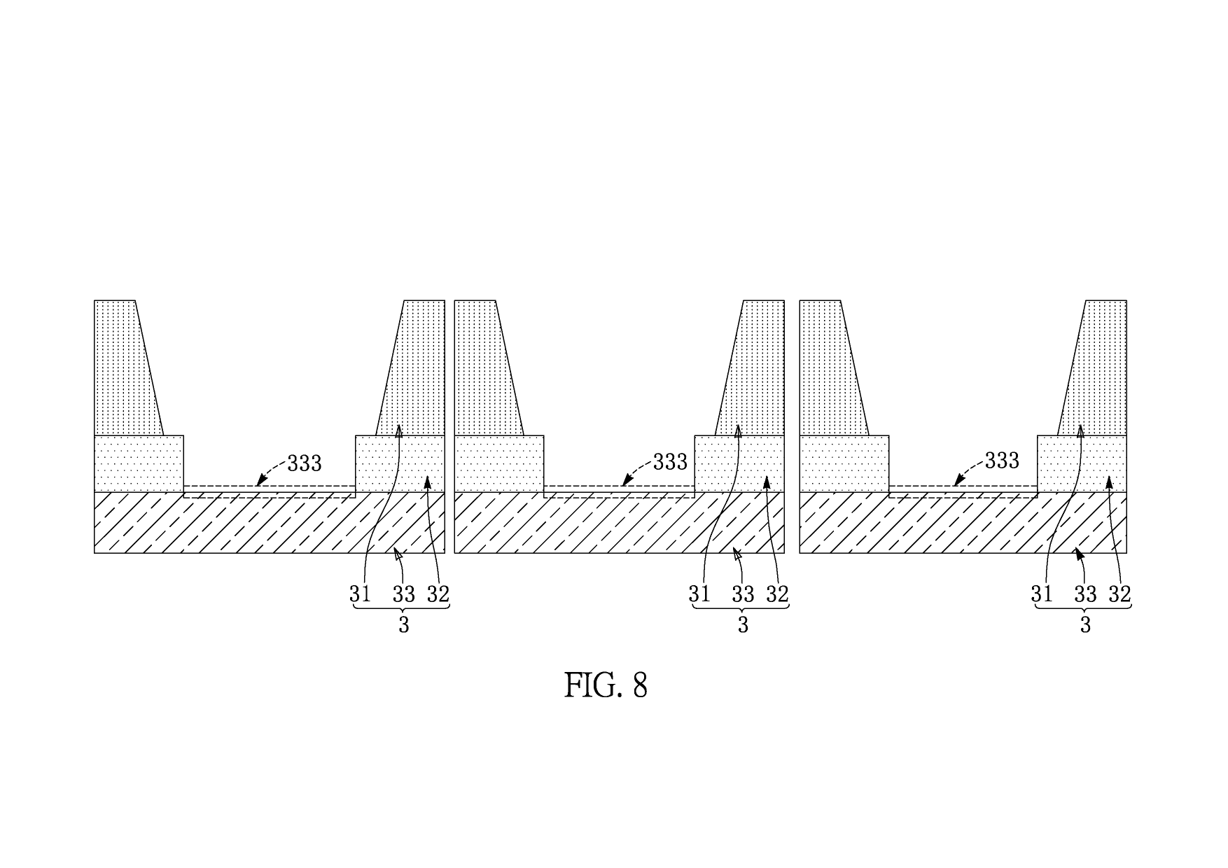

Next, the manufacturing method can proceed to step S302: cutting the light-transmitting layer, the supporting layer and the molding layer by using a dicing process to form the package cover. As shown in FIGS. 4 and 8, multiple ones of the package cover 3 can be obtained by cutting along cutting lines CL, and a quantity of the package covers 3 corresponds to a quantity of the predetermined sensing areas 333.

Step S303: providing a substrate, disposing a sensor chip on the first substrate surface and electrically connecting the sensor chip to the substrate, and disposing the package cover on the substrate.

In this step, reference can be made to the descriptions of FIGS. 1 and 2, a plurality of first pads 111 are provided on the first substrate surface 11, a plurality of second pads 212 located outside the sensing area 211 are disposed on the upper surface 21 of the sensor chip 2, and the plurality of first pads 111 are connected to the plurality of second pads 212 respectively through a plurality of metal wires 4.

Next, further referring to FIG. 1, the package cover 3 cooperatively formed by the molding layer 31, the supporting layer 32 and the light-transmitting layer 33 is disposed on the first substrate surface 11 (by having the first substrate surface 11 be in direct contact with the molding layer 31), and the package cover 3 directly surrounds the sensor chip 1, the plurality of first pads 111, the plurality of second pads 212 and the plurality of metal wires 4 in the enclosed space E.

Alternatively, further reference can be made to FIG. 2, in which the molding layer 31 is disposed in direct contact with the sensor chip 2, and only the sensing area 211 is surrounded by the package cover 3 cooperatively formed by the molding layer 31, the supporting layer 32 and the light-transmitting layer 33. Therefore, as shown in FIG. 2, a fourth vertical projection P4 of the molding layer 31 projected onto the sensor chip 2 is located between the sensing area 211 and the plurality of second pads 212, such that the sensor chip 2, the plurality of first pads 111 and the plurality of metal wires 4 are located outside the enclosed space E.

### Beneficial Effects of the Embodiments

In conclusion, in the sensor package structure and the manufacturing method thereof provided by the present disclosure, the package cover that is free of sealing epoxy resin is formed, thereby allowing a height and a width of the package cover to be precisely controlled, and effectively preventing the resin intrusion issue. Furthermore, process defects that may occur during the manufacturing process of the sensor package structure can be avoided, such as glass damage, scratches, or resin intrusion to a glass molding cover due to any improper contact during the molding process.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a sensor package structure, comprising:
providing a light-transmitting layer having a top surface and a bottom surface that are opposite to each other, wherein the light-transmitting layer has at least one predetermined sensing area on the bottom surface;
forming a supporting layer on the bottom surface of the light-transmitting layer, wherein the supporting layer surrounds the at least one predetermined sensing area;
forming a molding layer on the supporting layer by a molding process, wherein the molding layer surrounds the at least one predetermined sensing area;
cutting the light-transmitting layer, the supporting layer and the molding layer by using a dicing process to form at least one package cover;
providing a substrate having a first substrate surface and a second substrate surface that are opposite to each other;
disposing a sensor chip on the first substrate surface and electrically connecting the sensor chip to the substrate, wherein the sensor chip has a sensing area; and
disposing the at least one package cover on the first substrate surface of the substrate, wherein the light-transmitting layer, the supporting layer, the molding layer, and the first substrate surface of the substrate are formed to surround an enclosed space, and the sensor chip is located in the enclosed space.

2. The manufacturing method according to claim 1, wherein an area of a first vertical projection of the supporting layer projected onto the bottom surface is larger than an area of a second vertical projection of the molding layer projected onto the bottom surface.

3. The manufacturing method according to claim 1, wherein a quantity of the at least one predetermined sensing area is two or more, and the manufacturing method further comprises:
forming the supporting layer on the bottom surface of the light-transmitting layer, wherein the supporting layer surrounds each of the two or more predetermined sensing areas;
forming the molding layer on the supporting layer by using the molding process, wherein the molding layer surrounds each of the two or more predetermined sensing areas; and
cutting the light-transmitting layer, the supporting layer and the molding layer by using the dicing process to form the at least one package cover, wherein a quantity of the at least one package cover is two or more.

4. The manufacturing method according to claim 2, wherein a third vertical projection of the sensing area projected onto the bottom surface is spaced apart from the first vertical projection and the second vertical projection respectively by a first distance and a second distance, and the second distance is greater than the first distance.

5. The manufacturing method according to claim 2, wherein the molding layer has an inner surface adjacent to the enclosed space, and the inner surface is inclined to the first substrate surface.

6. The manufacturing method according to claim 2, wherein the step of forming the supporting layer on the bottom surface of the light-transmitting layer further includes:
forming a to-be-shaped supporting layer on the bottom surface of the light-transmitting layer by using a coating process; and
removing a part of the to-be-shaped supporting layer located on the at least one predetermined sensing area by using an etching process to form the supporting layer.

7. The manufacturing method according to claim 2, further comprising:
arranging a plurality of first pads on the first substrate surface;
arranging a plurality of second pads outside the sensing area on the upper surface of the sensor chip; and
connecting the plurality of first pads to the plurality of second pads respectively through a plurality of metal wires.

8. The manufacturing method according to claim 7, wherein the plurality of first pads and the plurality of metal wires are located in the enclosed space.

9. The manufacturing method according to claim 3, wherein, in the at least one package cover, an outer lateral surface of the supporting layer is coplanar with an outer lateral surface of the light-transmitting layer and an outer lateral surface of the molding layer.

10. The manufacturing method according to claim 7, wherein the at least one package cover is not in contact with the sensor chip, and the plurality of first pads are arranged along a projection that is defined by orthogonally projecting an inner side of the supporting layer onto the first substrate surface.

11. The manufacturing method according to claim 7, wherein a top part of each of the plurality of metal wires relative to the substrate is lower than the supporting layer.

12. The manufacturing method according to claim 7, wherein each of the plurality of metal wires has:
a first segment connected to a corresponding one of the plurality of first pads by a first angle; and
a second segment connected to the first segment and a corresponding one of the plurality of second pads;
wherein the molding layer has an inner surface adjacent to the enclosed space, and the inner surface is inclined to the first substrate surface by a second angle that is greater than the first angle.

13. The manufacturing method according to claim 1, wherein the at least one package cover is not in contact with the sensor chip, and the molding layer is free from contacting the light-transmitting layer through the supporting layer.

14. A sensor package structure manufactured by implementing the manufacturing method according to claim 1.

15. A manufacturing method of a sensor package structure, comprising:
providing a light-transmitting layer having a top surface and a bottom surface that are opposite to each other, wherein the light-transmitting layer has at least one predetermined sensing area on the bottom surface;
forming a supporting layer on the bottom surface of the light-transmitting layer, wherein the supporting layer surrounds the at least one predetermined sensing area;
forming a molding layer on the supporting layer by a molding process, wherein the molding layer surrounds the at least one predetermined sensing area;
cutting the light-transmitting layer, the supporting layer and the molding layer by using a dicing process to form at least one package cover;
providing a substrate having a first substrate surface and a second substrate surface that are opposite to each other;
disposing a sensor chip on the first substrate surface and electrically connecting the sensor chip to the substrate, wherein an upper surface of the sensor chip has a sensing area; and
disposing the at least one package cover on the upper surface of the sensor chip, wherein the light-transmitting layer, the supporting layer, the molding layer, and the upper surface of the sensor chip are formed to surround an enclosed space, and the sensing area is located in the enclosed space.

16. The manufacturing method according to claim 15, wherein an area of a first vertical projection of the supporting layer projected onto the bottom surface is larger than an area of a second vertical projection of the molding layer projected onto the bottom surface, and wherein a third vertical projection of the sensing area projected onto the bottom surface is spaced apart from the first vertical projection and the second vertical projection respectively by a first distance and a second distance, and the second distance is greater than the first distance.

17. The manufacturing method according to claim 16, wherein a fourth vertical projection of the molding layer projected onto the sensor chip is located between the sensing area and the plurality of second pads, such that the sensor chip, the plurality of first pads, and the plurality of metal wires are located outside the enclosed space.

18. The manufacturing method according to claim 15, wherein, in the at least one package cover, an outer lateral surface of the supporting layer is coplanar with an outer lateral surface of the light-transmitting layer and an outer lateral surface of the molding layer.

19. The manufacturing method according to claim 15, wherein the molding layer is free from contacting the light-transmitting layer through the supporting layer.

20. A sensor package structure manufactured by implementing the manufacturing method according to claim 15.
